(19) United States
(12) Patent Application Publication
(10) Pub. No.: US 2007/0194457 A1
(43) Pub. Date: Aug. 23, 2007

(54) Semiconductor package featuring thin semiconductor substrate and liquid crystal polymer sheet, and method for manufacturing such semiconductor package

(75) Inventors: Gorou Ikegami, Fukui (JP); Shunichi Iwanaga, Fukui (JP)

Correspondence Address: YOUNG & THOMPSON, 745 SOUTH 23RD STREET, 2ND FLOOR, ARLINGTON, VA, 22202, US

(73) Assignee: NEC ELECTRONICS COROPORATION, KAWASAKI (JP)

(21) Appl. No.: 11/709,223

(22) Filed: Feb. 22, 2007

(30) Foreign Application Priority Data
Feb. 22, 2006 (JP) 2006-045681

(51) Int. Cl. H01L 23/48; H01L 21/00

(52) U.S. Cl. 257/778; 438/108; 257/E23.021

(57) ABSTRACT

In a semiconductor package, a wiring board includes an insulating substrate, and a plurality of first electrode terminals formed on a surface thereof. A semiconductor chip includes a semiconductor substrate, and a plurality of second electrode terminals formed on a surface thereof, and is mounted on the wiring board so that the first electrode terminals are bonded to the second electrode terminals, respectively. A sealing layer is formed between the wiring board and the semiconductor chip so that the first electrode terminals and the second electrode terminals are sealed by the sealing layer, and so that the wiring board and the semiconductor chip are adhered to each other. The sealing s layer is derived from a liquid crystal polymer sheet intervened between the wiring board and the semiconductor chip. A difference between a linear thermal expansion coefficient of the insulating substrate and a linear thermal expansion coefficient of the semiconductor substrate is smaller than a difference between the linear thermal expansion coefficient of the semiconductor substrate and a linear thermal expansion coefficient of a glass epoxy substrate.

### BACKGROUND OF THE INVENTION

1. Field of the Invention

The present invention relates to a semiconductor package including a wiring board, and a semiconductor chip mounted on the wiring board through the intermediary of a sealing layer formed therebetween, and also relates to a method of manufacturing such a semiconductor package.

2. Description of the Related Art

Conventionally, a semiconductor package such a ball grid array (BGA) package includes a wiring board or interposer having a plurality of electrode pads formed on a surface thereof, and an array of solder balls bonded onto the other surface thereof. The semiconductor package also includes a flip-chip (FC) type semiconductor chip having a plurality of electrode terminals or metal bumps bonded onto a circuit formation face thereof.

In a first prior art method for manufacturing a semiconductor package, the FC type semiconductor chip is mounted on the wiring board so that the metal bumps are bonded onto the electrode pads of the interposer to thereby establish an electrical connection therebetween. Thereafter, the FC type semiconductor chip is underfilled with an uncured thermosetting resin material such as epoxy, and the thermosetting resin material is thermally cured to thereby form a sealing resin layer between the interposer and the FC type semiconductor chip. The sealing layer not only seals the metal bumps, but it also serves as an adhesion layer between the interposer and the FC type semiconductor chip.

The thermosetting resin material such as epoxy tends to contain moisture so that the semiconductor package may be broken due to a so-called popcorn phenomenon. In particular, when the semiconductor package is subjected to a heating process later, e.g., when a semiconductor package is mounted on a motherboard so that the array of solder balls are thermally bonded onto electrode pads formed on a surface of the motherboard, the moisture in the sealing resin layer is evaporated, resulting in the breakage of the semiconductor chip.

In a second prior art method for manufacturing a semiconductor package, as disclosed in, for example, JP-H11-307686 A and JP-2004-009948 A, a liquid crystal polymer sheet is substituted for the thermosetting resin material in the above-mentioned first prior art semiconductor package. In particular, since the liquid crystal polymer sheet exhibits a superior moisture barrier property, occurrence of the so-called popcorn phenomenon can be effectively prevented. Also, the liquid crystal polymer sheet exhibits a superior oxidation resistance.

### SUMMARY OF THE INVENTION

It has now been discovered that the above-mentioned prior art methods have a problem to be solved as will be mentioned in detail hereinafter.

In the above-mentioned first prior art semiconductor package, in the case where the thickness of the FC type semiconductor chip is too thin, the FC type semiconductor chip may be cracked when being mounted on the interposer, because the metal bumps of the FC type semiconductor package are pressed against the electrode pads on the interposer,

Also, in the above-mentioned second prior art semiconductor package, in the case where a difference between the linear thermal expansion coefficient of the FC type semiconductor chip and the linear thermal expansion coefficient of the interposer is too large, the semiconductor package may be warped and/or the metal bumps may be crack and be peeled when the semiconductor package is subjected to a thermal stress.

In accordance with a first aspect of the present invention, there is provided a semiconductor package, which comprises: a wiring board including an insulating substrate, and a plurality of first electrode terminals formed on a surface thereof; a semiconductor chip including a semiconductor substrate, and a plurality of second electrode terminals formed on a surface thereof, and mounted on the wiring board so that the first electrode terminals are bonded to the second electrode terminals, respectively; and a sealing layer formed between the wiring board and the semiconductor chip so that the first electrode terminals and the second electrode terminals are sealed by the sealing layer, and so that the wiring board and the semiconductor chip are adhered to each other. The sealing layer is derived from a liquid crystal polymer sheet intervened between the wiring board and the semiconductor chip. A difference between the linear thermal expansion coefficient of the insulating substrate and the linear thermal expansion coefficient of the semiconductor substrate is smaller than a difference between the linear thermal expansion coefficient of the semiconductor substrate and the linear thermal expansion coefficient of a glass epoxy substrate.

Each of the first electrode terminals of the wiring board may be formed as an electrode pad, and each of the second electrode terminals of the semiconductor chip may be formed as a metal bump. Otherwise, each of the first electrode terminals of the wiring board may be formed as a metal bump, and each of the second electrode terminals of the semiconductor chip may be formed as an electrode pad.

The insulating substrate of the wiring board may be formed as either a ceramic substrate or a polyimide substrate. The semiconductor substrate of the semiconductor chip has a thickness which falls within a range from 20 to 80 μm.

In accordance with a second aspect of the present invention, there is provided a method for manufacturing a semiconductor package, which method comprises: preparing a wiring board including an insulating substrate, and a plurality of electrode pads formed on a surface thereof; preparing a semiconductor chip including a semiconductor substrate, and a plurality of metal bumps formed on a surface thereof; placing a liquid crystal polymer sheet on the first electrode terminals of the wiring board; heating the electrode pads, the metal bumps and the liquid crystal polymer sheet to a predetermined temperature; positioning the semiconductor chip with respect to the wiring board so that the metal bumps are aligned with the electrode pads; and pressing the semiconductor chip against the liquid crystal polymer sheet so that the metal bumps penetrate into the liquid crystal polymer sheet, and so that the metal bumps are abutted against and bonded on to the electrode pads.

In accordance with a third aspect of the present invention, there is provided a method for manufacturing a semiconductor package, which method comprises: preparing a wiring board including an insulating substrate, and a plurality of metal bumps formed on a surface thereof; preparing a semiconductor chip including a semiconductor substrate, and a plurality of electrode pads formed on a surface thereof; placing a liquid crystal polymer sheet on the first electrode terminals of the wiring board; heating the metal bumps, the electrode pads and the liquid crystal polymer sheet to a predetermined temperature; positioning the semiconductor chip with respect to the wiring board so that the electrode pads are aligned with the metal bumps; and pressing the semiconductor chip against the liquid crystal polymer sheet so that the metal bumps penetrate into the liquid crystal polymer sheet, and so that the metal bumps are abutted against and bonded on to the electrode pads.

### BRIEF DESCRIPTION OF THE DRAWINGS

The present invention will be more clearly understood from the description set forth below, as compared with prior art methods for manufacturing semiconductor packages, with reference to the accompanying drawings, wherein;

FIGS. 1A and 1B are explanatory views for a first prior art method for manufacturing a semiconductor package;

FIGS. 2A, 2B and 2C are explanatory views for a second prior method for manufacturing a semiconductor package;

FIGS. 3A and 3B are explanatory views for a first embodiment of a method for manufacturing a semiconductor package according to the present invention; and

FIGS. 4A and 4B are explanatory views for a second embodiment of a method for manufacturing a semiconductor package according to the present invention.

### DESCRIPTION OF THE PREFERRED EMBODIMENTS

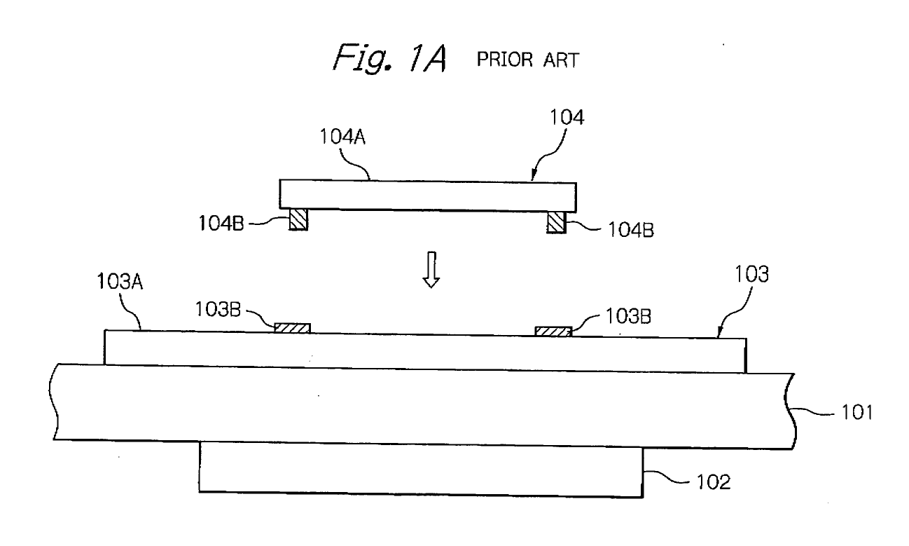

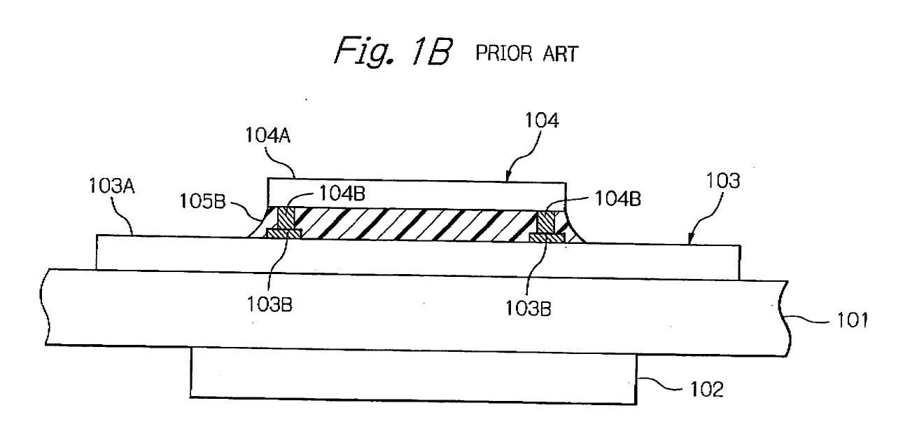

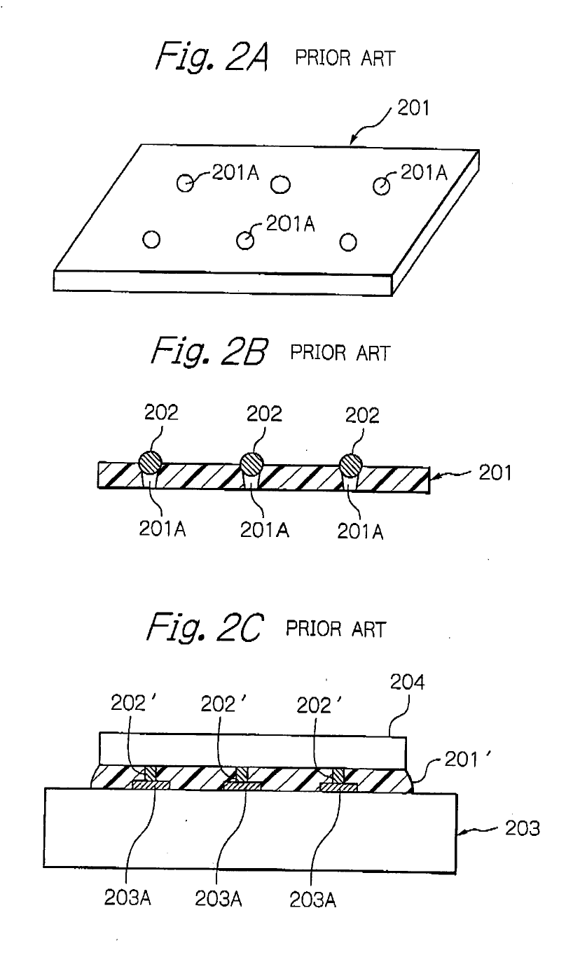

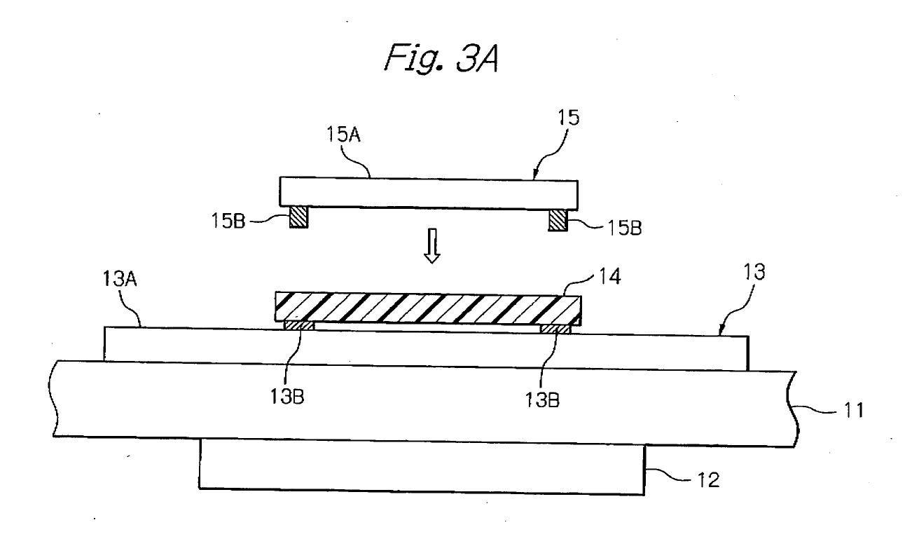

Before a description of embodiments of the present invention, for better understanding of the present invention, with reference to FIGS. 1A and 1B and FIGS. 2A, 2B and 2C, prior art methods for manufacturing a semiconductor package will be described below.

A first prior art method for manufacturing a semiconductor package is now explained with reference to FIGS. 1A and 1B which are partial cross-sectional views.

First, referring to FIG. 1A, reference numeral 101 indicates a stage which forms a part of a flip-chip bonding machine, and the stage 101 is provided with an electric heater unit 102,

An interposer or wiring board 103 is set on the stage 101. The wiring board 103 includes an insulating substrate 103A composed of a suitable material such as polyimide, glass epoxy, ceramic or the like, and a plurality of electrode pads 103B formed on a surface of the insulating substrate 103A. Note, only two of the electrode pads 103B are representatively shown in FIG. 1A.

A flip-chip (FC) type semiconductor chip 104 is detachably supported by a movable tool (not shown) which forms another part of the flip-chip bonding machine, and is upwardly and downwardly movable with respect to the wiring board 103. The FC type semiconductor chip 104 includes a semiconductor substrate 104A such as a gallium/arsenic (GsAs) substrate, a silicon (Si) substrate or the like, and a plurality of metal bumps 104B bonded onto a surface circuit formation face of the semiconductor substrate 104A. Note, only two of the metal bumps 104B are representatively shown in FIG. 1A.

As indicated by an open arrow in FIG. 1A, the FC type semiconductor chip 104 is moved downwardly toward the wiring board 103 so that the metal bumps 104B are abutted and pressed against the electrode pads 103B while the wiring board 104 is heated to a given temperature by electrically energizing the electric heater unit 102, resulting in bonding the metal bumps 104B onto the electrode pads 103B. Note that the FC type semiconductor chip 104 is preheated by an electric heater contained in the movable tool (not shown).

Next, referring to FIG. 1B, the FC type semiconductor chip 104 is underfilled with a suitable thermosetting resin material, and the thermosetting resin material is cured so that a sealing resin layer 105 is formed between the wiring board 104 and the FC type semiconductor chip 104, resulting in production of a semiconductor package including the wiring board 103, the FC type semiconductor chip 104 mounted on the wiring board 103, and the sealing resin layer 105 formed therebetween. The sealing resin layer 105 not only seals the electrode pads 103B and the metal bumps 104B, but also it serves as an adhesion layer between the wiring board 104 and the FC type semiconductor chip 104.

The first prior art manufacturing method needs the two heating processes: one to bond the metal bumps 104B onto the electrode pads 103B; and the other is cure the thermosetting resin material. Also, the underfilling process is relatively troublesome.

Thus, the first prior art manufacturing method is costly. Especially, when semiconductor chips are mounted on both the surfaces of the wiring board 103, the first prior art manufacturing method is inefficient.

Further, the thermosetting resin material tends to contain moisture so that the semiconductor package may be broken due to the above-mentioned popcorn phenomenon,

A second prior art manufacturing method, as disclosed in JP-H11-307686 A, is now explained with reference to FIGS. 2A, 2B and 2C.

First, referring to FIG. 2A which is a perspective view, a liquid crystal polymer sheet 201 is prepared. A plurality of through holes 201A are formed in the liquid crystal polymer sheet 201.

Next, referring to FIG. 2B which is a cross-sectional view taken the 2B-2B line of FIG. 2A, a plurality of solder balls 202 are set in the respective through holes 201A. Note that the solder balls 202 have a diameter somewhat larger than that of the through holes 201A.

Next, referring to FIG. 2C which is a cross-sectional view, the liquid crystal polymer sheet 201 carrying the solder balls 202 are set on a wiring board 203 so that the respective through holes 201A are aligned with electrode pads 203A formed on a surface of the wiring board 203.

Then, an FC type semiconductor chip 204 is placed on the liquid crystal polymer sheet 201 so that electrode pads (not shown) formed on a circuit formation face of the PC type semiconductor chip 204 are registered with the respective solder balls 201A.

Subsequently, while the wiring board 203 is heated to a given temperature, the FC type semiconductor chip 204 is pressed against the wiring board 203, whereby the solder balls 202 are thermally fused under a pressurized state so that each of the through holes 201A is charged with the fused solder ball so that the solder plugs 202′ are formed in the respective through holes 201A, to thereby establish an electrical connection between the wiring board 203 and the FC type semiconductor chip 204 due to the formation of the solder plugs 202′, resulting in production of a semiconductor package including the wiring board 203, and the FC type semiconductor chip 204 mounted on the wiring board 203.

On the other hand, the liquid crystal polymer sheet 201 is also thermally fused under the pressurized state, and is adhered to both the wiring board 203 and the FO type semiconductor chip 204 so that a sealing layer 201′ is formed by the liquid crystal polymer sheet 201 between the wiring board 203 and the FC type semiconductor chip 204. Namely, the sealing layer 201′ not only seals the solder plugs 201′, but it also serves as an adhesive layer between the wiring board 203 and the FC type semiconductor chip 204.

As already stated above, since the sealing layer 201′ derived from the liquid crystal polymer sheet 201 exhibits a superior moisture barrier property, the semiconductor package of FIG. 2C is free from the popcorn phenomenon.

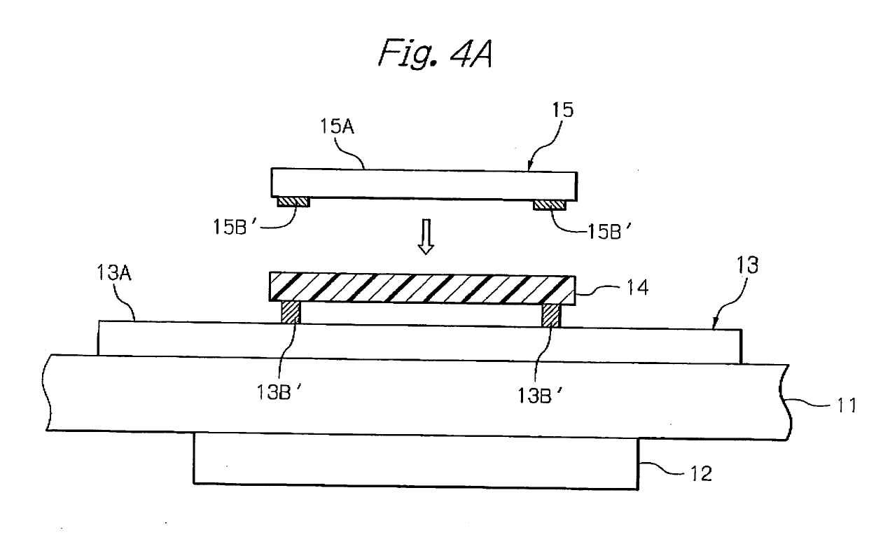

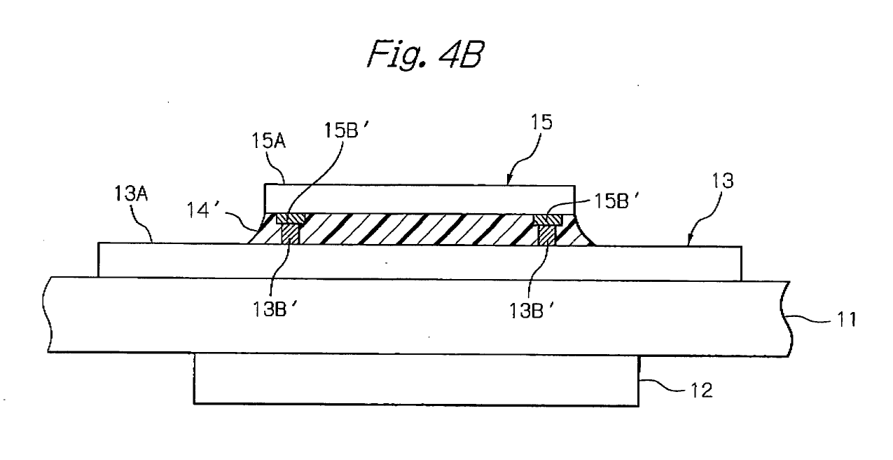

Nevertheless, since the wiring board 203 is formed as a glass epoxy substrate, as disclosed in JP-H11-307686 A, the semiconductor package of FIG. 4C may be warped when being put under a high temperature, because the glass epoxy substrate has a larger linear coefficient of expansion than that of a semiconductor substrate of the FC type semiconductor chip 204, which may be formed as a gallium/arsenic (GsAs) substrate, a silicon (Si) substrate or the like.

The GsAs substrate is more fragile in comparison with the Si substrate. Thus, the GsAs substrate may be easily damaged and cracked when being subjected to thermal stresses due to temperature variation. On the other hand, when the Si substrate is too thin in thickness, it also may be subjected to being damaged and cracked. Similarly, the solder plugs 202′ may be damaged and crack.

### First Embodiment

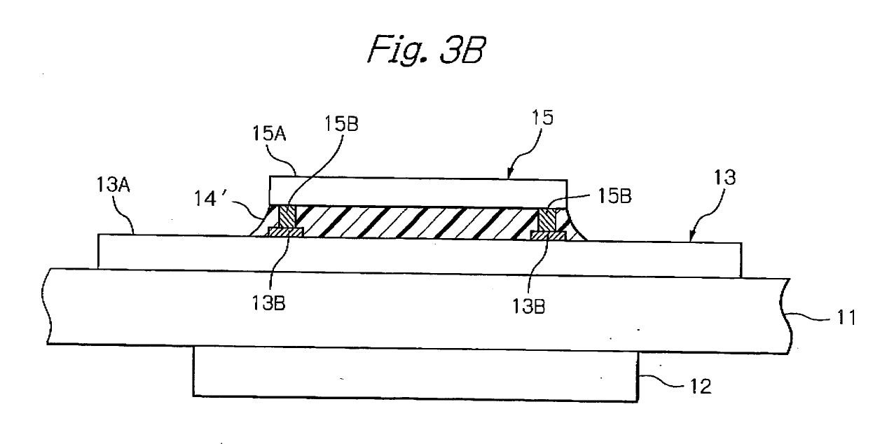

A first embodiment of the method for manufacturing a semiconductor package according to the present invention is now explained with reference to FIGS. 3A and 3B which are partial cross-sectional views.

First, referring to 3A, reference numeral 11 indicates a stage which forms a part of a flip-chip bonding machine, and the stage 11 is provided with an electric heater unit 12.

An interposer or wiring board 13 is set on the stage 11. The wiring board 13 includes an insulating substrate or ceramic substrate 13A, and a plurality of electrode terminals 13B formed on a surface of the ceramic substrate 13A, and each of the electrode terminals 13B is defined as an electrode pad. Then, a liquid crystal polymer sheet 14 is placed on the electrode pads 13B of the wiring board 13. Note that only two of the electrode pads 13B are representatively shown in FIG. 3A.

A flip-chip (FC) type semiconductor chip 15 is detachably supported by a movable tool (not shown) which forms another part of the flip-chip bonding machine, and is upwardly and downwardly movable with respect to the wiring board 13. The FC type semiconductor chip 15 includes a semiconductor substrate 15A such as a gallium/arsenic (GsAs) substrate, a silicon (Si) substrate or the like, and a plurality of electrode terminals 15B bonded onto a circuit formation face of the semiconductor substrate 15A, and each of the electrode terminals 15B is defined as a metal bump. Note that only two of the metal bumps 15B are representatively shown in FIG. 3A.

Then, as indicated by an open arrow in FIG. 3A, the FC type semiconductor chip 15 is moved downwardly toward the wiring board 13, while both the wiring board 13 and the liquid crystal polymer sheet 14 are heated to a given temperature by electrically energizing the electric heater unit 12 so that the liquid crystal polymer sheet 14 is thermally fused. Note that the FC type semiconductor chip 15 is preheated by an electric heater contained in the movable tool.

Next, referring to FIG. 3B, when the metal bumps 15B are abutted and pressed against the liquid crystal polymer sheet 14, the metal bumps 15B can easily penetrate into the liquid crystal polymer sheet 14, and then are thermally bonded onto the electrode pads 13B so that proper mechanical and electrical connections can be established therebetween, with a sealing layer 14′ being formed by the liquid crystal polymer sheet 14 between the wiring board 13 and the FC type semiconductor chip 15. The sealing layer 14′ not only seals the electrode pads 13B and the metal bumps 15B, but it also serves as an adhesive layer between the wiring board 13 and the FC type semiconductor chip 15.

When an external force is exerted on a thermally fused liquid crystal polymer, molecules of liquid crystal polymer are oriented in a flowing direction of the liquid crystal polymer, because the shape of the molecules cannot be varied by the external force due to the fact that the molecules of liquid crystal polymer contain no straight-chain C-C bonds.

Thus, when the metal bumps 15B are pressed against the liquid crystal polymer sheet 14, a virtual viscosity of the crystal polymer sheet 14 is abruptly made small at the locations at which the metal bumps 15B are pressed against the liquid crystal polymer sheet 14, whereby the metal bumps 15B can easily penetrate into the liquid crystal polymer sheet 14 so that the proper mechanical and electrical connections between the electrode pads 133 and the metal bumps 15B cannot be retarded by the fused liquid crystal polymer (14).

### Second Embodiment

A second embodiment of the method for manufacturing a semiconductor package according to the present invention is now explained with reference to FIGS. 4A and 4B which respectively correspond to FIGS. 3A and 3B.

The second embodiment is substantially identical to the first embodiment of FIGS. 3A and 3B except that a plurality of metal bumps 13B′ are substituted for the electrode pads 13B of the wiring board 13, and that a plurality of electrode pads 15B′ are substituted for the metal bumps 15B of the FC type semiconductor chip 15.

First, referring to FIG. 4A, the liquid crystal polymer sheet 14 is placed on the metal bumps 13B′ of the wiring board 13.

Then, as indicated by an open arrow in FIG. 4A, the FC type semiconductor chip 15 is moved downwardly toward the wiring board 13, while both the wiring board 13 and the liquid crystal polymer sheet 14 are heated to a given temperature by electrically energizing the electric heater unit 12 so that the liquid crystal polymer sheet 14 is thermally fused.

Next, referring to FIG. 4B, when the electrode pads 15B′ are abutted and pressed against the liquid crystal polymer sheet 14, the metal bumps 13S′ can easily penetrate into the liquid crystal polymer sheet 14 for the same reasons as in the above-mentioned first embodiment of FIGS. 3A and 3B, and then are thermally bonded onto the electrode pads 15B′ so that proper mechanical and electrical connections can be established therebetween, with the sealing layer 14′ being formed by the liquid crystal polymer sheet 14 between the wiring board 13 and the FC type semiconductor chip 15. Similar to the above-mentioned first embodiment, the sealing layer 14′ not only seals the metal bumps 13B′ and the electrode pads 15B′, but it also serves as an adhesive layer between the wiring board 13 and the FC type semiconductor chip 15.

### EXAMPLE

Chip-mounting tests were carried out by the inventors. In the chip-mounting tests, the following items were used:

1) Wiring boards including a ceramic substrate having a 11 mm×16 mm size, and a 1 m thickness;

2) FC type GaAs chips having a 1.05 mm×1.8 mm size and a 55 μm thickness including a 25 μm thickness of a gold electrode plating layer; and

3) FA type liquid crystal polymer sheets having a 50 μm thickness, which were available as Vecstar (Registered Trademark) from KURARAY Co., Ltd.

Also, the chip-mounting tests were carried out in a flip-chip bonding machine under the following conditions:

1) Temperature of a movable tool: 300° C.

2) Temperature of a stage: 250° C.

3) Pressing time: 30 seconds

Note that a pressure load exerted on one metal bump was varied by 10 g within the range from 10 g to 60 g.

In the test results, there were no cracks in all the FC type GaAs chips.

Further, although the semiconductor packages obtained by the chip-mounting tests were subjected to thermal stress tests, none of the semiconductor packages could be warped, and there were no cracks and no peelings in the metal bumps due to the fact that a difference between the linear thermal expansion coefficient of the ceramic substrates and the linear thermal expansion coefficient of the FC type GaAs chips is small.

### Comparative Example

Also, comparative chip-mounting tests were carried out by the inventors under substantially the same conditions as in the aforesaid EXAMPLE except that no liquid crystal polymer sheets were used.

In the test results, when the pressure load exerted on one metal bump was more than 30 g, there were cracks in the FC type GaAs chips at a location at which each of the metal bumps was abutted against the FC type GaAs chips, because the pressure stresses were concentrated at the aforesaid location due to the fact the ceramic substrate is harder than the glass epoxy substrate (JP-H11-307686 A). Namely, the pressure stresses could not be absorbed by the ceramic substrate due to the hardness thereof.

On the contrary, in the aforesaid EXAMPLE, since the pressure stresses could be absorbed by the liquid crystal polymer sheet, they could not be directly exerted onto the FC type GaAs chips.

Further, each of the semiconductor packages obtained by the comparative chip-mounting tests was underfilled with a thermosetting resin material. Then, after the thermosetting resin material was cured, although the semiconductor package was subjected to a thermal stress test, it could not be warped, and there were no cracks and no peelings in the metal bumps. Of course, this is because the difference between the linear thermal expansion coefficient of the ceramic substrates and the linear thermal expansion coefficient of the FC type GaAs chips is small,

The manufacturing method according to the present invention can be advantageously and effectively applied to a fragile semiconductor substrate having a thickness from 20 to 80 μm. The semiconductor substrate having a thickness of less than 20 μm cannot be practically used in a semiconductor package. Also, the semiconductor substrate having a thickness of more than 80 μm is free from the above-mentioned crack problem.

It is preferable that the liquid crystal polymer sheet is formed as an aromatic liquid crystal polymer having a thermal fusing point, which is somewhat lower than the bonding temperature of the metal bumps.

In the above-mentioned embodiments, the wiring board 13 may include a polyimide substrate which is substituted for the ceramic substrate 13A, because a difference between the linear thermal expansion coefficient of the polyimide substrate and the linear thermal expansion coefficient of the semiconductor substrate is small.

Finally, it will be understood by those skilled in the art that the foregoing description is of preferred embodiments of the package and the method, and that various changes and modifications may be made to the present invention without departing from the spirit and scope thereof.

1. A semiconductor package comprising:
a wiring board including an insulating substrate, and a plurality of first electrode terminals formed on a surface thereof;
a semiconductor chip including a semiconductor substrate, and a plurality of second electrode terminals formed on a surface thereof, and mounted on said wiring board so that said first electrode terminals are bonded to said second electrode terminals, respectively; and
a sealing layer formed between said wiring board and said semiconductor chip so that said first electrode terminals and said second electrode terminals are sealed by said sealing layer, and so that said wiring board and said semiconductor chip are adhered to each other,
wherein said sealing layer is derived from a liquid crystal polymer sheet intervened between said wiring board and said semiconductor chip, and
wherein a difference between a linear thermal expansion coefficient of said insulating substrate and a linear thermal expansion coefficient of said semiconductor substrate is smaller than a difference between the linear thermal expansion coefficient of said semiconductor substrate and a linear thermal expansion coefficient of a glass epoxy substrate.

2. The semiconductor package as set forth in claim 1, wherein each of the first electrode terminals of said wiring board is formed as an electrode pad, and each of the second electrode terminals of said semiconductor chip is formed as a metal bump.

3. The semiconductor package as set forth in claim 1, wherein each of the first electrode terminals of said wiring board is formed as a metal bump, and each of the second electrode terminals of said semiconductor chip is formed as an electrode pad.

4. The semiconductor package as set forth in claim 1, wherein the insulating substrate of said wiring board is formed as a ceramic substrate.

5. The semiconductor package as set forth in claim 1, wherein the insulating substrate of said wiring board is formed as a polyimide substrate.

6. The semiconductor package as set forth in claim 1, wherein the semiconductor substrate of said semiconductor chip has a thickness which falls within a range from 20 to 80 μm.

7. A method for manufacturing a semiconductor package, which method comprises:
preparing a wiring board including an insulating substrate, and a plurality of electrode pads formed on a surface thereof;
preparing a semiconductor chip including a semiconductor substrate, and a plurality of metal bumps formed on a surface thereof;
placing a liquid crystal polymer sheet on the first electrode terminals of said wiring board;
heating said electrode pads, said metal bumps and said liquid crystal polymer sheet to a predetermined temperature;
positioning said semiconductor chip with respect to said wiring board so that said metal bumps are aligned with said electrode pads; and
pressing said semiconductor chip against said liquid crystal polymer sheet so that said metal bumps penetrate into said liquid crystal polymer sheet, and so that said metal bumps are abutted against and bonded on to said electrode pads.

8. A method for manufacturing a semiconductor package, which method comprises:
preparing a wiring board including an insulating substrate, and a plurality of metal bumps formed on a surface thereof;
preparing a semiconductor chip including a semiconductor substrate, and a plurality of electrode pads formed on a surface thereof;
placing a liquid crystal polymer sheet on the first electrode terminals of said wiring board;
heating said metal bumps, said electrode pads and said liquid crystal polymer sheet to a predetermined temperature;
positioning said semiconductor chip with respect to said wiring board so that said electrode pads are aligned with said metal bumps; and
pressing said semiconductor chip against said liquid crystal polymer sheet so that said metal bumps penetrate into said liquid crystal polymer sheet, and so that said metal bumps are abutted against and bonded on to said electrode pads.
